(19) United States
(12) Patent Application Publication
(10) Pub. No.: US 2024/0032361 A1
(43) Pub. Date: Jan. 25, 2024

(54) DISPLAY DEVICE

(71) Applicant: Samsung Display Co., LTD., Yongin-si (KR)

(72) Inventor: INYOUNG JUNG, Seoul (KR)

(21) Appl. No.: 18/354,884

(22) Filed: Jul. 19, 2023

(30) Foreign Application Priority Data
Jul. 21, 2022 (KR) 10-2022-0090290

(51) Int. Cl. H10K 59/131; H10K 59/121; H10K 59/123

(52) U.S. Cl. CPC H10K 59/131; H10K 59/121; H10K 59/123

(57) ABSTRACT

A display device includes a display area, a metal line which is connected to the display area, transmits a first signal to the display area and extends along a first direction, a gate line which is connected to the display area, transmits a second signal to the display area and extends along a second direction crossing the first direction, the gate line crossing the metal line and defining an opening of the gate line which overlaps the metal line, and a first bridge pattern extending across the opening in the gate line and crossing the metal line, the first bridge pattern contacting the gate line at two contact locations along the gate line.

This application claims priority to Korean Patent Application No. 10-2022-0090290 filed on Jul. 21, 2022 and all the benefits accruing therefrom under 35 U.S.C. § 119, the entire disclosure of which is incorporated by reference herein.

### BACKGROUND

### 1. Field

Embodiments relate to a display device. More particularly, embodiments relate to a display device and a method of repairing the display device.

### 2. Description of the Related Art

The display device is a device that displays an image for providing visual information such as to a user. Among display devices, an organic light emitting diode display has received attention.

An organic light emitting display device includes a transistor (e.g., thin film transistor) and a light emitting diode which is driven by the transistor, to realize an image. That is, when an electrical current is supplied to the light emitting diode, through the transistor, a light emitting operation occurs within the light emitting diode and an image is realized using emitted light.

### SUMMARY

Since various lines connected to the transistor (e.g., signal lines such as a gate line and a data line) are formed with fine line widths, when an electrical short circuit occurs between different-layer lines overlapping each other, repair to such lines may be needed

Embodiments provide a display device capable of being repaired, while maintaining an electrical signal path even when the repair is complete.

A display device according to an embodiment may include a substrate, a metal line disposed on the substrate and extending in a first direction, a gate line disposed on the metal line, extending in a second direction crossing the first direction and defining an opening overlapping the metal line and a conductive pattern disposed on the gate line and connected to the gate line through at least two contacts.

In an embodiment, the contacts may be spaced apart from each other in the second direction, and the opening may be defined between the contacts.

In an embodiment, the gate line may include a first portion and a second portion spaced apart from each other, and each of the first portion and the second portion may overlap the metal line.

In an embodiment, the first portion and the second portion may be spaced apart from each other in the first direction, and the opening may be positioned between the first portion and the second portion in a plan view.

In an embodiment, the first portion and the second portion may be spaced apart from the conductive pattern in the first direction in the plan view.

In an embodiment, the display device may further include a buffer layer covering the metal line, an active pattern disposed on the buffer layer, a gate electrode disposed on the active pattern and overlapping the active pattern, a first insulation layer disposed on the gate electrode, a source electrode and a drain electrode disposed on the first insulation layer and connected to the active pattern, a second insulation layer disposed on the source electrode and the drain electrode and a pixel electrode disposed on the second insulation layer and connected to one of the source electrode and the drain electrode.

In an embodiment, the gate line may be disposed on a same layer as the gate electrode.

In an embodiment, the conductive pattern may be disposed on a same layer as the source electrode and the drain electrode.

In an embodiment, the display device may further include a bridge pattern disposed on a same layer as the pixel electrode.

In an embodiment, the bridge pattern may be connected to the conductive pattern.

In an embodiment, the bridge pattern may be spaced apart from the first portion and the second portion in the first direction in the plan view.

In an embodiment, at least one first hole may be defined in the first insulation layer, at least one second hole overlapping the first hole may be defined in the second insulation layer, and the first hole and the second hole may form a hole portion.

In an embodiment, the hole portion may overlap at least one of the first portion and the second portion in the plan view, and be spaced apart from the metal line.

In an embodiment, the conductive pattern may be disposed on a same layer as the pixel electrode.

In an embodiment, the display device may further include at least one metal pattern disposed on a same layer as the metal line, overlapping at least one of the first portion and the second portion in the plan view, and spaced apart from the metal line.

In an embodiment, the metal line may transmit a data signal, and the gate line transmits a gate signal.

A display device according to an embodiment may include a substrate, a metal line disposed on the substrate and extending in a first direction, a gate line disposed on the metal line, extending in a second direction crossing the first direction, and branched to have a plurality of paths in at least one of areas overlapping the metal line and a conductive pattern disposed on the gate line and connected to the gate line through at least two contacts.

In an embodiment, the gate line may have a shape combined into one path in front and rear ends of the area branching to have the plurality of paths.

In an embodiment, the contacts may be respectively adjacent to the front and the rear ends of the area of the gate line branching to have the plurality of paths.

In an embodiment, the area of the gate line branching to have the plurality of paths may be spaced apart from the conductive pattern in the plan view.

In a display device according to embodiments of the present disclosure, since the display device further includes a conductive pattern connected to the gate line on the gate line, the gate signal may be transmitted through the conductive pattern without being interrupted. Specifically, when a short circuit occurs in the display device before forming the conductive pattern, even if both the first portion and the second portion of the gate line are cut to eliminate the short circuit, the cut gate line may transmit the gate signal through the conductive pattern. Accordingly, even if both the first portion and the second portion of the gate line are cut due to an invisible defect in a repair process of the display device, the display device may be repaired.

In addition, since the laser is irradiated from the top of the display device in the repair process, damage to the substrate due to the laser may be prevented.

Even when both the first and second portions of the gate line are cut, the gate line may be electrically connected due to the conductive pattern. Accordingly, the gate signal may be transmitted through the gate line while solving the short circuit of the display device.

### BRIEF DESCRIPTION OF THE DRAWINGS

The above and other advantages and features of this disclosure will become more apparent by describing in further detail embodiments thereof with reference to the accompanying drawings, in which:

FIG. 1 is a plan view of a display device according to an embodiment.

FIG. 2 is an enlarged plan view illustrating area A of FIG. 1.

FIGS. 3A and 3B are views illustrating a cross-sectional view taken along line I-I′ of FIG. 1 and a cross-sectional view taken along line II-II′ of FIG. 2, respectively.

FIG. 4 is an enlarged plan view illustrating an embodiment of area A in FIG. 1.

FIGS. 5A and 5B are views illustrating a cross-sectional view taken along line I-I′ of FIG. 1 and a cross-sectional view taken along line III-III′ of FIG. 4, respectively.

FIG. 6 is an enlarged plan view illustrating an embodiment of area A in FIG. 1.

FIG. 7 is an enlarged plan view illustrating an embodiment of area A in FIG. 1.

FIG. 8 is an enlarged plan view illustrating an embodiment of area A in FIG. 1.

FIGS. 9A and 9B are views illustrating a cross-sectional view taken along line I-I′ of FIG. 1 and a cross-sectional view taken along line IV-IV′ of FIG. 8, respectively.

FIG. 10 is an enlarged plan view illustrating an embodiment of area A in FIG. 1.

FIG. 11 is an enlarged plan view illustrating an embodiment of area A in FIG. 1.

FIGS. 12A and 12B are views illustrating a cross-sectional view taken along line I-I′ of FIG. 1 and a cross-sectional view taken along line V-V′ of FIG. 11, respectively.

FIGS. 13A and 13B are views illustrating is a cross-sectional view taken along line I-I′ of FIG. 1 and a cross-sectional view taken along line VI-VI′ of FIG. 11, respectively.

FIGS. 14A and 14B are views illustrating a cross-sectional view taken along line I-I′ of FIG. 1 and a cross-sectional view taken along line VI-VI′ of FIG. 11, respectively.

FIG. 15 is an enlarged plan view illustrating an embodiment of area A in FIG. 1.

FIGS. 16 to 20 are enlarged plan views illustrating a repair method according to an embodiment of the present disclosure.

FIGS. 21 to 23 are enlarged plan views illustrating a repair method according to an embodiment of the present disclosure.

FIGS. 24 and 25 are enlarged plan views illustrating a repair method according to an embodiment of the present disclosure.

FIGS. 26 to 29 are variously enlarged plan and enlarged cross-sectional views illustrating a repair method according to an embodiment of the present disclosure.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. A reference number labeling a singular form of an element within the drawing figures may be used to reference a plurality of the singular element within the text of specification.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

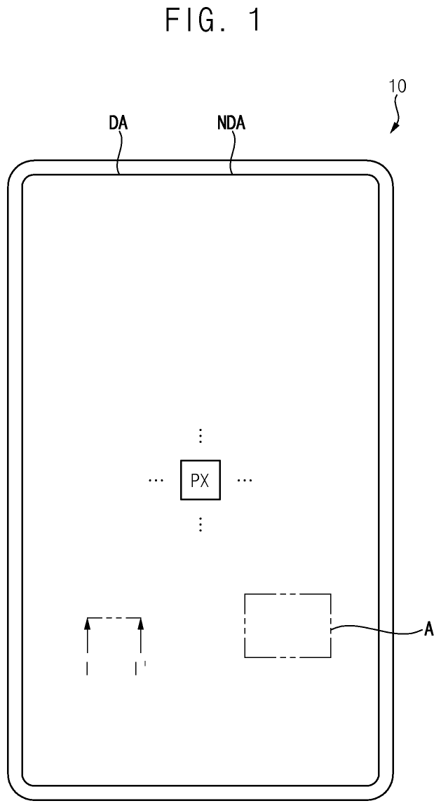

FIG. 1 is a plan view of a display device 10 according to an embodiment.

Referring to FIG. 1, the display device 10 may include a display area DA and a non-display area NDA. The display area DA may be an area (e.g., a planar area) for displaying an image. A planar shape of the display area DA may be a rectangular shape or a rectangular shape with rounded corners as shown in FIG. 1. However, the planar shape of the display area DA is not limited thereto, and the display area DA may have various planar shapes such as a circle, an ellipse, and a polygon. Various components or layers of the display device 10 may include a display area DA and a non-display area NDA corresponding to those described above.

The non-display area NDA may be disposed, such as extending around the display area DA. In an embodiment, the non-display area NDA may surround the display area DA. The non-display area NDA may be an area that does not display an image. In an embodiment, drivers for driving elements within the display area DA to display an image in the display area DA, may be disposed in the non-display area NDA and connected to the elements of the display area DA.

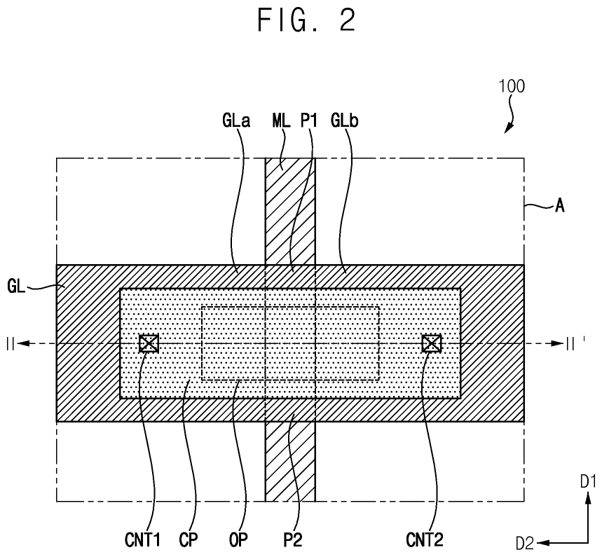

A pixel PX provided in plural including a plurality of pixels may be arranged in a matrix in the display area DA. Signal lines such as a gate line (e.g., the gate line GL of FIG. 2) and a data line (e.g., the metal line ML of FIG. 2) may be disposed in the display area DA. The signal lines such as the gate line GL and the data line may be connected to one or more pixel PX among the pixels PX. Each of the pixels PX may receive a gate signal as a first signal, a data signal as a second signal, and the like, from the signal line.

FIG. 2 is an enlarged plan view illustrating area A of FIG. 1. Area A may be adjacent to a transistor area at which the transistor TR is disposed, without being limited thereto.

Referring to FIGS. 1 and 2, the display device 10 may include a display panel 100. An area A may be one area among planar areas in the display area DA of the display panel 100. The display panel 100 may include a metal line ML, a gate line GL, and a conductive pattern CP.

The metal line ML may extend in the first direction D1. The gate line GL may be disposed on the metal line ML, in a third direction, and may extend in the second direction D2. The second direction D2 may cross the first direction D1, and the third direction may cross each of the first direction D1 and the second direction D2. The conductive pattern CP may be disposed on the gate line GL, in (or along) the third direction. The conductive pattern CP may have an elongated shape in the second direction D2. As used herein, an element which extends in a direction may have a major dimension thereof along the direction (e.g., an extension direction), without being limited thereto. A thickness of the display device 10 and various components or layers thereof, may be defined along the third direction, to define a thickness direction.

The metal line ML may transmit the data signal to the pixels PX. The gate line GL may transmit the gate signal to the pixels PX.

The gate line GL may define at least one opening OP overlapping (or corresponding to) the metal line ML. That is, the gate line GL may be branched at the opening OP, to have a plurality of paths (e.g., an electrical path provided in plural including a plurality of electrical paths) in at least one of the areas overlapping the metal line ML. The opening OP may be defined in an area of the gate line GL at which the gate line GL is branched to have the plurality of paths.

For example, the gate line GL may define one opening OP, and may be branched to have two paths in at least one of the areas which is adjacent to the opening and overlapping the metal line ML. However, the present disclosure is not limited thereto. The gate line GL may define two or more openings, and may be branched to have three or more paths in at least one of the areas overlapping the metal line ML. A planar area at which the gate line GL overlaps the metal line ML, may define an overlapping area.

The gate line GL may include a first portion P1 and a second portion P2 spaced apart from each other. Where a length (e.g., major dimension) of the gate line GL extends along the second direction D2, a width of the gate line GL which is a dimension smaller than the length, may extend along the first direction D1. The first portion P1 and the second portion P2 may be spaced apart from each other along the width of the gate line GL., That is, the first portion P1 and the second portion P2 may be portions respectively corresponding to the plurality of paths (e.g., the plurality of electrical paths). Each of the first portion P1 and the second portion P2 may overlap the metal line ML.

Within a signal line, an electrical signal may flow along an electrical path in an electrical flow direction. The gate line GL may have a shape combined into one path in (or at) a front end GLa and a rear end GLb of the area which branches to have the plurality of paths. That is, the front end of the first portion P1 and the front end of the second portion P2 may be combined into one electrical path, and the rear end of the first portion P1 and the rear end of the second portion P2 may be combined into one electrical path. In an embodiment, a front end GLa may follow the rear end GLb in the electrical flow direction, or vice versa. In an embodiment, the two overlapping portions of the gate line GL (e.g., the first portion P1 and the second portion P2) meet each other at a front end GLa of a gap (e.g., the opening OP) and at a rear end GLb of the gap which is opposite to the front end along the second direction D2.

The gate line GL may branch into the first portion P1 and the second portion P2 due to the opening OP therebetween. The first portion P1 and the second portion P2 may be spaced apart from each other in (or along) the first direction D1. In a plan view, the opening OP may be disposed between the first portion P1 and the second portion P2. Specifically, a width in the second direction D2 of each of the first portion P1 and the second portion P2 may be the same as the width of the opening OP in the second direction D2.

The conductive pattern CP as a first bridge pattern, may be connected to the gate line GL at or through at least two contacts CNT1 and CNT2. In an embodiment, a first bridge pattern (e.g., the conductive pattern CP) extends across the opening OP in the gate line GL and crosses the metal line ML, the first bridge pattern contacting the gate line GL at two contact locations (e.g., the contacts CNT1 and CNT2) along the gate line GL. Each of the contacts CNT1 and CNT2 may be a through hole penetrating the first insulation layer ILD. For example, the conductive pattern CP may be connected to the gate line GL, at the two contacts CNT1 and CNT2. However, the present disclosure is not limited thereto. The two contact locations (e.g., the two contacts CNT1 and CNT2) are respectively further from the gap than the front end GLa and the rear end GLb.

The contacts CNT1 and CNT2 may be spaced apart from each other in the second direction D2. For example, the first contact CNT1 (e.g., a first contact location) may be spaced apart from the second contact CNT2 (e.g., a second contact location spaced apart from the first contact location along the gate line GL) in the second direction D2. The opening OP may be positioned between the contacts CNT1 and CNT2 in the plan view. In addition, the metal line ML may also be positioned between the contacts CNT1 and CNT2 in the plan view. That is, the contacts CNT1 and CNT2 may be disposed adjacent to the front end Gla and the rear end GLb of the area of the gate line GL branching to have the plurality of paths, respectively. For example, the first contact CNT1 may be adjacent to the front end Gla, and the second contact CNT2 may be adjacent to the rear end GLb.

In an embodiment, as the display device 10 further includes the conductive pattern CP on the gate line GL and connected to the gate line GL, the gate signal may be transmitted through the conductive pattern CP without interruption. Specifically, when a short circuit occurs in the display device 10, such as before forming the conductive pattern CP in a method of providing the display device 10, the first portion P1 and the second portion P2 of the gate line GL may be cut to eliminate the short circuit. Even in this case, the cut gate line GL may transmit the gate signal through the conductive pattern CP as a bypass pattern. With the portions of the gate line GL being cut or electrically disconnected from each other, the electrical signal (e.g., the gate signal) may bypass the portions and be transmitted via the bypass pattern. Accordingly, in the case of an invisible defect in the repair process of the display device 10, even if both the first portion P1 and the second portion P2 of the gate line GL are cut, the display device 10 may be repaired.

In addition, since a laser is irradiated from the top of the display device 10 in the repair process (refer to FIGS. 27 and 29), damage to the substrate SUB disposed as a bottom layer of the display device 10 due to the laser may be prevented.

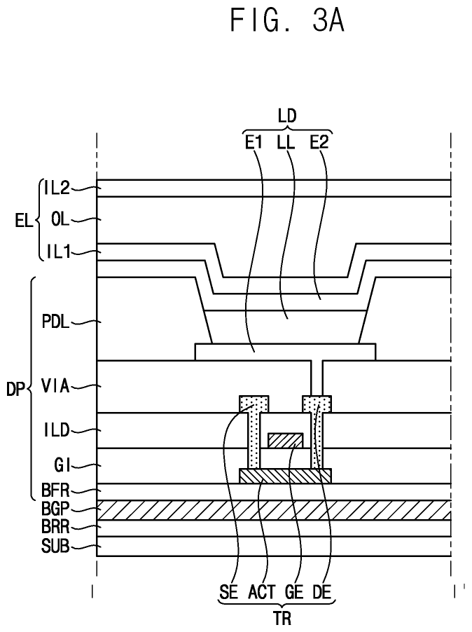

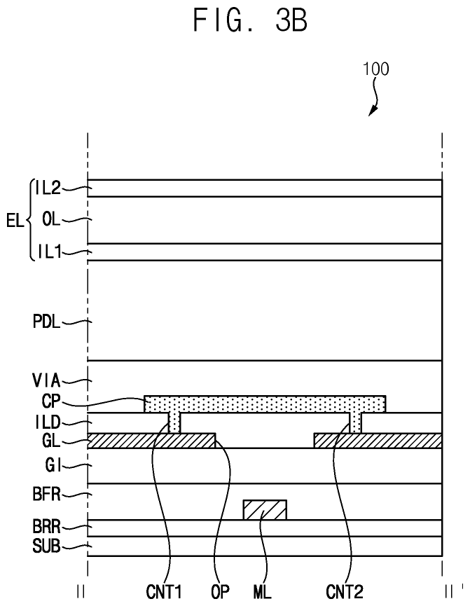

FIGS. 3A and 3B (together referred to as FIG. 3, hereinafter) are views illustrating a cross-sectional view taken along line I-I′ of FIG. 1 and a cross-sectional view taken along line II-II′ of FIG. 2, respectively.

For example, the line I-I′ of FIG. 1 and the line II-II′ of FIG. 2 may be cross-sectional views of different areas, such as different areas within the display area DA of FIG. 1.

Referring to FIGS. 1 to 3, the display panel 100 may include a substrate SUB, a barrier layer BRR, a back-gate pattern BGP, a display part DP, and an encapsulation layer EL. The display part DP may include a buffer layer BFR, a gate insulation layer GI, a first insulation layer ILD, a transistor TR, a second insulation layer VIA, a pixel defining layer PDL, and a light emitting diode LD may be included. The transistor TR may include an active pattern ACT, a source electrode SE, a gate electrode GE, and a drain electrode DE which may be disposed together in a display circuit layer. The light emitting diode LD as a light-emitting element may include a pixel electrode E1, an light emitting layer LL, and a common electrode E2 which may be disposed together in a light-emitting element layer. The encapsulation layer EL may include a first inorganic encapsulation layer IL1, an organic encapsulation layer EL, and a second inorganic encapsulation layer IL2.

The substrate SUB may include a transparent material or an opaque material. Examples of the material constituting the substrate SUB include plastic, polyethersulfone, polyacrylate, polyetherimide, polyarylate, polyimide, and the like. The above substances may be used alone or in combination. For example, the substrate SUB may include polyimide. However, the material constituting the substrate SUB is not limited thereto, and the substrate SUB may include a glass material including silicon.

The barrier layer BRR may be disposed on the substrate SUB. The barrier layer BRR may prevent foreign substances from penetrating through the substrate SUB. Examples of the material constituting the barrier layer BRR may include silicon oxide, silicon nitride, silicon oxynitride, and the like. The above substances may be used alone or in combination. The barrier layer BRR may be entirely disposed in the display area DA.

The metal line ML and the back-gate pattern BGP may each be disposed on the barrier layer BRR. That is, the metal line ML and the back-gate pattern BGP may be disposed on the same layer. As being on a same layer, elements may be formed in a same process and/or as including a same material, elements may be in a same layer as each other as respective portions of a same material layer, may each form an interface with a same underlying or overlying layer, etc., without being limited thereto. Also, the metal line ML and the back-gate pattern BGP may be spaced apart from each other, in a direction along the substrate SUB. However, the present disclosure is not limited thereto, and the metal line ML and the back-gate pattern BGP may be connected to each other.

The back-gate pattern BGP may include a conductive material. For example, examples of the conductive material constituting the back-gate pattern BGP may include aluminum, platinum, palladium, silver, magnesium, gold, nickel, neodymium, iridium, chromium, lithium, calcium, molybdenum, titanium, tungsten, and copper. And the like. The above substances may be used alone or in combination.

The metal line ML may include a conductive material. For example, the metal line ML may include the same material as the back-gate pattern BGP.

The buffer layer BFR may be disposed on the back-gate pattern BGP and the metal line ML. The buffer layer BFR may cover the back-gate pattern BGP and the metal line ML. The buffer layer BFR may prevent penetration of foreign substances from the back-gate pattern BGP and the metal line ML. Examples of the material constituting the buffer layer BFR include silicon oxide, silicon nitride, and silicon oxynitride. The above substances may be used alone or in combination.

An active pattern ACT may be disposed on the buffer layer BFR. The active pattern ACT may overlap the back-gate pattern BGP. The active pattern ACT may include a semiconductor material. For example, the active pattern ACT may include a silicon-based semiconductor material. Alternatively, the active pattern ACT may include an oxide-based semiconductor material.

The gate insulation layer GI may be disposed on the buffer layer BFR. The gate insulation layer GI may cover the active pattern ACT. The gate insulation layer GI may insulate the active pattern ACT from the gate electrode GE. The gate insulation layer GI may include an inorganic insulating material. For example, the gate insulation layer GI may include silicon oxide, silicon nitride, silicon oxynitride, or the like.

The gate electrode GE and the gate line GL may be disposed on the gate insulation layer GI. That is, the gate line GL may be disposed on the same layer as the gate electrode GE. In an embodiment, the gate electrode GE may be connected to the gate line GL and may receive an electrical signal such as the gate signal, from the gate line GL.

The gate electrode GE may overlap the active pattern ACT. The gate electrode GE may include a conductive material. For example, examples of the conductive material constituting the gate electrode GE may include aluminum, platinum, palladium, silver, magnesium, gold, nickel, neodymium, iridium, chromium, lithium, calcium, molybdenum, titanium, tungsten, copper, and the like. The above substances may be used alone or in combination.

The gate line GL may include a conductive material. For example, the gate line GL may include the same material as the gate electrode GE.

The first insulation layer ILD may be disposed on the gate insulation layer GI. The first insulation layer ILD may be disposed on the gate electrode GE and the gate line GL, and may cover the gate electrode GE and the gate line GL. The first insulation layer ILD may insulate the gate electrode GE from the source electrode SE. Also, the first insulation layer ILD may insulate the gate electrode GE from the drain electrode DE. The first insulation layer ILD may include an inorganic insulating material. For example, examples of the inorganic insulating material constituting the first insulation layer ILD may include silicon oxide, silicon nitride, silicon oxynitride, and the like. The above substances may be used alone or in combination.

The source electrode SE, the drain electrode DE, and the conductive pattern CP may be disposed on the first insulation layer ILD. That is, the conductive pattern CP may be disposed on the same layer as the source electrode SE and the drain electrode DE.

The source electrode SE and the drain electrode DE may be disposed on the active pattern ACT and may be connected to the active pattern ACT. For example, the source electrode SE may contact one end of the active pattern ACT through (or at) a through hole penetrating the first insulation layer ILD and the gate insulation layer GI. For example, the drain electrode DE may contact the other end of the active pattern ACT through (or at) a through hole penetrating the first insulation layer ILD and the gate insulation layer GI. As being in contact, elements may form an interface therebetween, without being limited thereto.

As described above, the conductive pattern CP may be disposed on the gate line GL and may be connected to the gate line GL.

Each of the source electrode SE and the drain electrode DE may include a conductive material. For example, examples of the conductive material constituting the source electrode SE and the drain electrode DE may include aluminum, platinum, palladium, silver, magnesium, gold, nickel, neodymium, iridium, chromium, lithium, calcium, molybdenum, titanium, tungsten, copper, and the like. The above substances may be used alone or in combination.

The conductive pattern CP may include a conductive material. For example, the conductive pattern CP may include the same material as the source electrode SE and the drain electrode DE.

The second insulation layer VIA may be disposed on the first insulation layer ILD. The second insulation layer VIA may be disposed on the source electrode SE, the drain electrode DE, and the conductive pattern CP. The source electrode SE, the drain electrode DE, and the conductive pattern CP may be covered by the second insulation layer VIA.

The second insulation layer VIA may have a flat top surface. The top surface may be a surface which is furthest from the substrate SUB. The second insulation layer VIA may include an organic insulating material. For example, examples of the organic insulating material constituting the second insulation layer VIA may include acryl, benzocyclobutene (BCB), hexamethyldisiloxane (HMDSO), and the like. The above substances may be used alone or in combination.

The pixel electrode E1 may be disposed on the second insulation layer VIA. The pixel electrode E1 may be electrically connected to the drain electrode DE. For example, the pixel electrode E1 may be connected to one of the source electrode SE and the drain electrode DE through (or at) a through hole penetrating the second insulation layer VIA. The pixel electrode E1 may include a conductive material. For example, examples of the conductive material constituting the pixel electrode El may include silver (Ag), ITO, IZO, IGO, AZO, and IGZO. The above substances may be used alone or in combination.

The pixel defining layer PDL may be disposed on the second insulation layer VIA. The pixel defining layer PDL may cover at least a portion of the pixel electrode E1. The pixel defining layer PDL may include (or define) an opening exposing at least a portion of the pixel electrode E1 to outside the pixel defining layer PDL.

The light emitting layer LL may be disposed on the pixel electrode E1. The light emitting layer LL may include a hole injection layer, a hole transport layer, an organic emission layer, an electron injection layer, and/or an electron transport layer. The light emitting layer LL may emit light by driving of the pixel PX and/or the light-emitting element. Alternatively, the light emitting layer LL may include an organic light emitting material or an inorganic light emitting material.

The common electrode E2 may be disposed on the pixel defining layer PDL. The common electrode E2 may be disposed to cover the emission layer LL. The common electrode E2 may include a metal having a relatively small work function. For example, examples of the material constituting the common electrode E2 may include lithium, calcium, aluminum, silver, magnesium, and the like. The above substances may be used alone or in combination.

The active pattern ACT, the gate electrode GE, the source electrode SE, and the drain electrode DE may together define the transistor TR. The pixel electrode E1, the emission layer LL, and the common electrode E2 may together define the light emitting diode LD. The emission layer LL may be electrically connected to the transistor TR through (or at) the pixel electrode E1. Accordingly, the light emitting layer LL may receive an electrical signal from the transistor TR and emit light having a luminance corresponding to the strength of the electrical signal.

The first inorganic encapsulation layer IL1 may be disposed on the pixel defining layer PDL and the common electrode E2. The first inorganic encapsulation layer IL1 may be disposed on the pixel defining layer PDL and the common electrode E2, and may cover the pixel defining layer PDL and the common electrode E2. Examples of the material constituting the first inorganic encapsulation layer IL1 may include silicon oxide, silicon nitride, silicon oxynitride, and the like. The above substances may be used alone or in combination.

The organic encapsulation layer OL may be disposed on the first inorganic encapsulation layer ILL Since the first inorganic encapsulation layer IL1 is formed along a lower structure to have a profile conforming to the underlying structure, an upper surface of the first inorganic encapsulation layer IL1 may not be flat. In contrast, the organic encapsulation layer OL may have a substantially flat top surface. Examples of the material constituting the organic encapsulation layer OL may include polyethylene terephthalate, polyethylene naphthalate, polycarbonate, polyimide, polyethylene sulfonate, polyoxymethylene, polyarylate, hexamethyldisiloxane, acrylic resin, and the like. The above substances may be used alone or in combination.

The second inorganic encapsulation layer IL2 may be disposed on the organic encapsulation layer OL. Examples of the material constituting the second inorganic encapsulation layer IL2 include silicon oxide, silicon nitride, and silicon oxynitride. The above substances may be used alone or in combination. The first inorganic encapsulation layer IL1, the organic encapsulation layer OL, and the second inorganic encapsulation layer IL2 may prevent penetration of moisture, oxygen, etc. from the outside of the display device The first inorganic encapsulation layer IL1, the organic encapsulation layer OL and the second inorganic encapsulation layer IL2 may constitute the encapsulation layer EL.

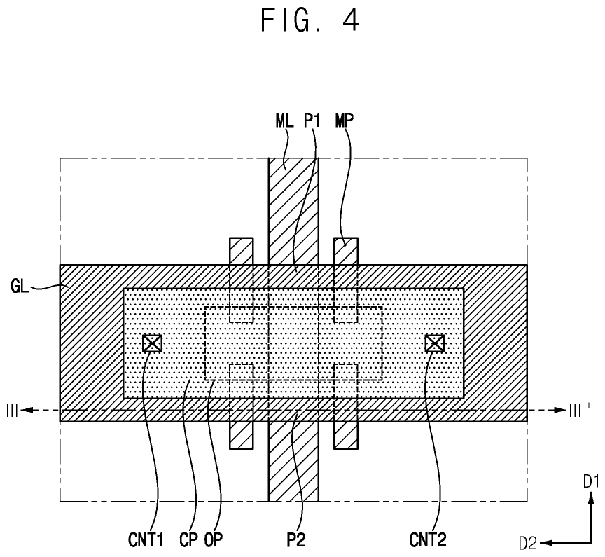

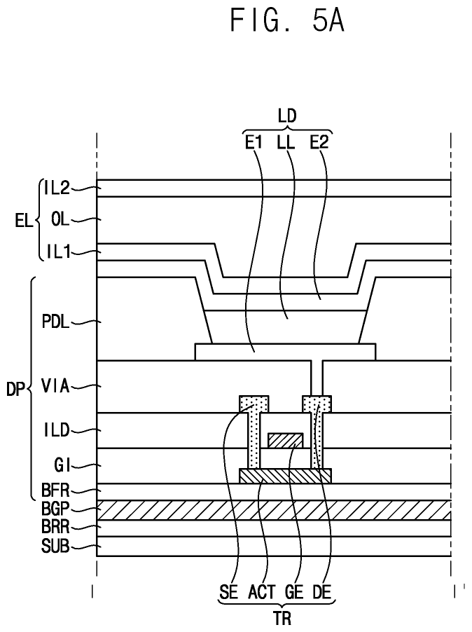

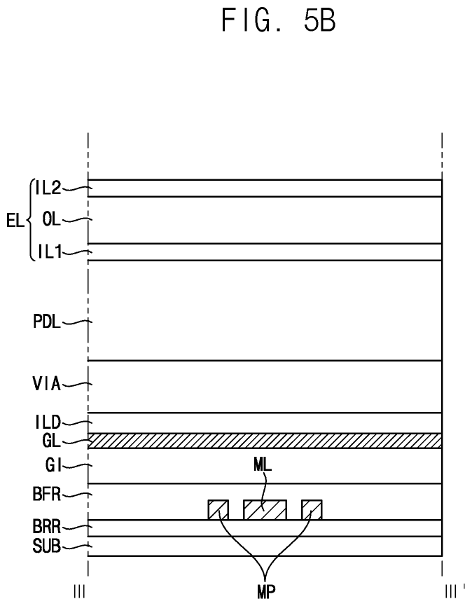

FIG. 4 is a plan view illustrating an embodiment of area A in FIG. 1. FIGS. 5A and (together referred to as FIG. 5, hereinafter) are views illustrating a cross-sectional view taken along line I-I′ of FIG. 1 and a cross-sectional view taken along line III-III′ of FIG. 4, respectively.

Among a description of the display device 10 described with reference to FIGS. 4 and 5, a description that overlaps with the display device 10 described with reference to FIG. 2 may be omitted.

Referring to FIGS. 4 and 5, in an embodiment, the display device 10 may further include at least one metal pattern MP. The metal pattern MP may be disposed on the same layer as the metal line ML. That is, the metal pattern MP may be disposed on the barrier layer BRR, and the buffer layer BFR may cover the metal pattern MP. The metal pattern MP may be electrically floating, that is, electrically disconnected from other conductive patterns, without being limited thereto. The metal pattern MP may be a discrete pattern (or island-shape pattern).

The metal pattern MP may overlap at least one of the first portion P1 and the second portion P2 in the plan view. The metal pattern MP may be spaced apart from the metal line ML. However, the present disclosure is not limited thereto, and the metal pattern MP may be connected to the metal line ML.

For example, the display device 10 may include four metal patterns MP. However, the present disclosure is not limited thereto. The metal patterns MP may be disposed with the metal line ML interposed therebetween in the plan view. Each of the metal patterns MP may overlap the first portion P1 or the second portion P2. The metal line ML and the metal patterns MP may together form a metal pattern layer.

In an embodiment, when the gate line GL is cut with a laser during the repair process of the display device 10, as the laser is irradiated onto the metal patterns MP (e.g., at a cutting position correspond to a metal pattern MP), the display device 10 may be prevented from being damaged. Specifically, since the display device 10 further includes the metal patterns MP, damage to the substrate SUB under the gate line GL (and under the metal pattern layer) may be prevented through the metal patterns MP.

FIG. 6 is a plan view illustrating an embodiment of area A in FIG. 1.

Among a description of the display device 10 described with reference to FIG. 6, a description that overlaps with the display device 10 described with reference to FIG. 2 may be omitted.

Referring to FIG. 6, the first portion P1 and the second portion P2 of the gate line GL may be spaced apart from the conductive pattern CP, in the first direction D1, in the plan view. That is, an area of the gate line GL branched to have the plurality of paths may be spaced apart from the conductive pattern CP in the plan view.

In an embodiment, since the first portion P1 and the second portion P2 of the gate line GL are spaced apart from the conductive pattern CP, even when a short circuit occurs in the display device 10 after forming the conductive pattern CP in a method process, the gate line GL may be cut without damaging the conductive pattern CP. Accordingly, even when the gate line GL is cut, the gate signal may be transmitted without being interrupted through the conductive pattern CP as a bypass pattern.

FIG. 7 is a plan view illustrating an embodiment of an area A in FIG. 1.

Among a description of the display device 10 described with reference to FIG. 7, a description that overlaps with the display device 10 described with reference to FIGS. 4 and 6 may be omitted.

Referring to FIG. 7, the display device 10 may further include at least one metal pattern MP. The metal pattern MP may be disposed on the same layer as the metal line ML. The metal pattern MP may overlap at least one of the first portion P1 and the second portion P2 in the plan view. The metal pattern MP may be spaced apart from the metal line ML.

For example, the display device 10 may include four metal patterns MP. The metal patterns MP may be disposed with the metal line ML interposed therebetween in the plan view. Each of the metal patterns MP may overlap the first portion P1 or overlap the second portion P2.

In an embodiment, when the gate line GL is cut with a laser during the repair process of the display device 10, the laser is irradiated onto the metal patterns MP, and thus the substrate SUB included in the display device 10 may be prevented from being damaged.

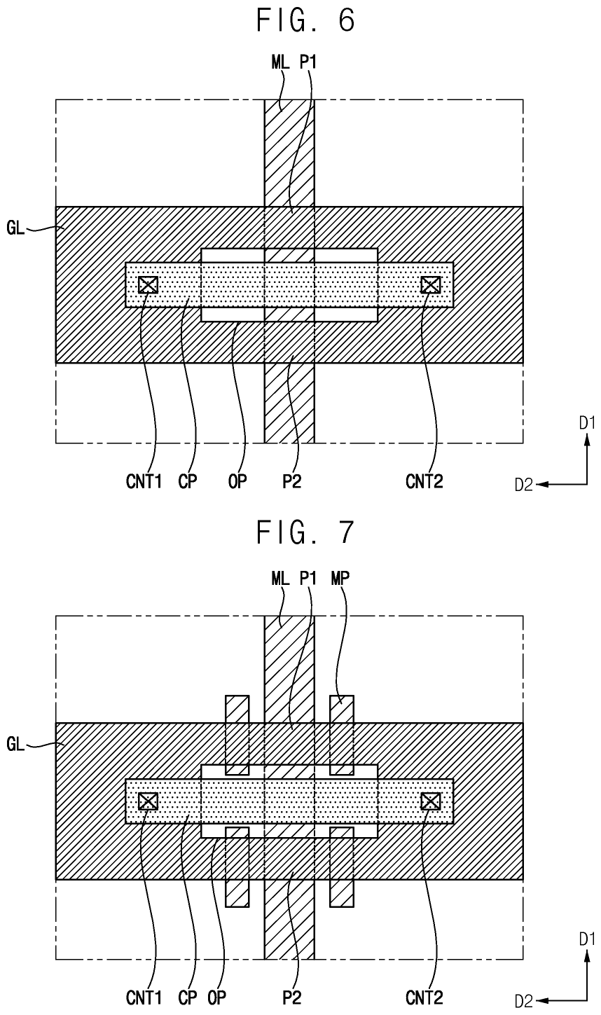

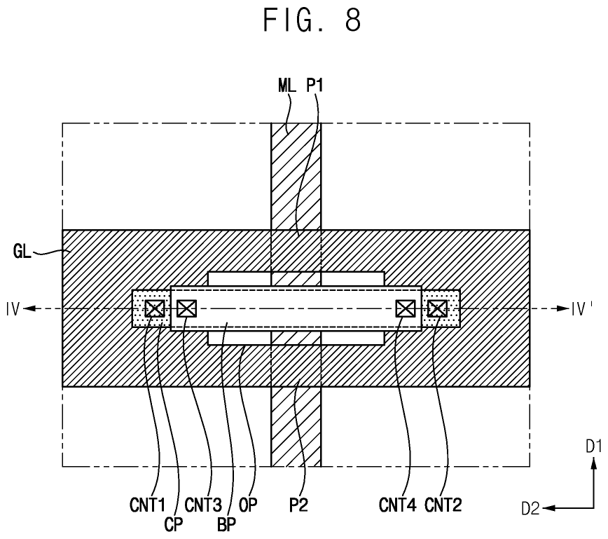

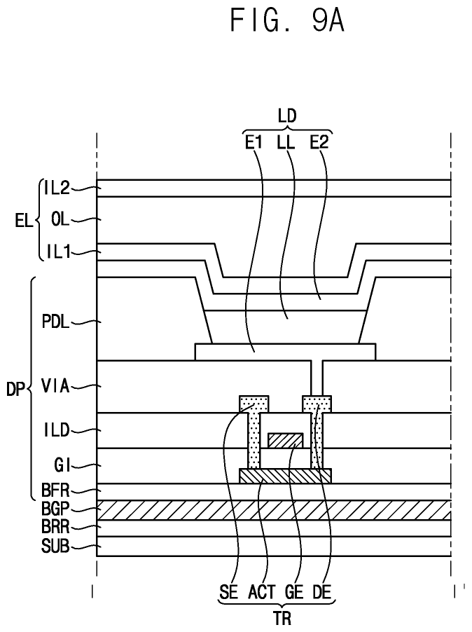

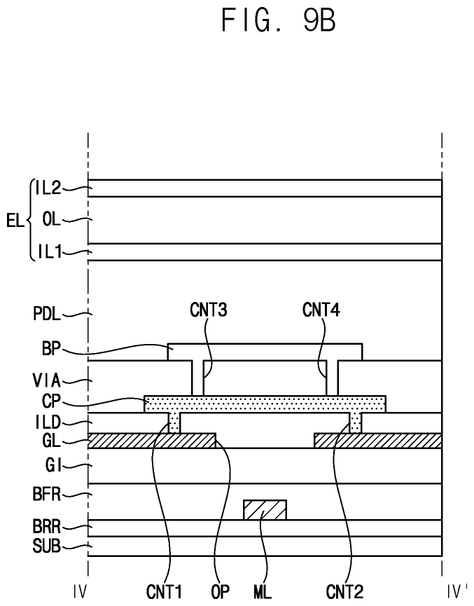

FIG. 8 is a plan view illustrating an embodiment of area A in FIG. 1. FIGS. 9A and 9B (together referred to as FIG. 9, hereinafter) are views illustrating a cross-sectional view taken along line I-I′ of FIG. 1 and a cross-sectional view taken along line IV-IV′ of FIG. 8, respectively.

Among a description of the display device 10 described with reference to FIGS. 8 and 9, a description that overlaps with the display device 10 described with reference to FIG. 6 may be omitted.

Referring to FIGS. 8 and 9, in an embodiment, the display device 10 may further include a bridge pattern BP.

The bridge pattern BP may be disposed on the same layer as the pixel electrode El. That is, the bridge pattern BP may be disposed on the second insulation layer VIA. For example, the bridge pattern BP may include the same material as the pixel electrode El.

The bridge pattern BP as a second bridge pattern may be connected to the conductive pattern CP through contacts CNT3 and CNT4 (e.g., a third contact location and a fourth contact location along the gate line GL). The bridge pattern BP may be spaced apart from the first portion P1 and the second portion P2, in the first direction D1, in the plan view.

In an embodiment, both the first portion P1 and the second portion P2 of the gate line GL may be cut in the repair process. Even at this time, since the bridge pattern BP is connected to the conductive pattern CP, the cut gate line GL may transmit the gate signal through the conductive pattern CP and the bridge pattern BP. Accordingly, even if both the first portion P1 and the second portion P2 of the gate line GL are cut due to an invisible defect in the repair process of the display device 10, the display device 10 may be repaired.

In addition, as the bridge pattern BP is spaced apart from the first portion P1 and the second portion P2, when a short circuit occurs after the pixel electrode El and the bridge pattern BP are formed, the display device 10 may be repaired. In this case, the gate line GL may be cut without damaging the conductive pattern CP and the bridge pattern BP.

FIG. 10 is a plan view illustrating an embodiment of area A in FIG. 1.

Among a description of the display device 10 described with reference to FIG. 10, a description that overlaps with the display device 10 described with reference to FIGS. 4 and 8 may be omitted.

Referring to FIG. 10, the display device 10 may further include at least one metal pattern MP. The metal pattern MP may be disposed on the same layer as the metal line ML. The metal pattern MP may overlap at least one of the first portion P1 and the second portion P2 in the plan view. The metal pattern MP may be spaced apart from the metal line ML.

For example, the display device 10 may include four metal patterns MP. The metal patterns MP may be disposed with the metal line ML interposed therebetween in the plan view.

In an embodiment, when the gate line GL is cut with a laser during the repair process of the display device 10, as the laser is irradiated onto the metal patterns MP, and thus the substrate SUB included in the display device 10 may be prevented from being damaged.

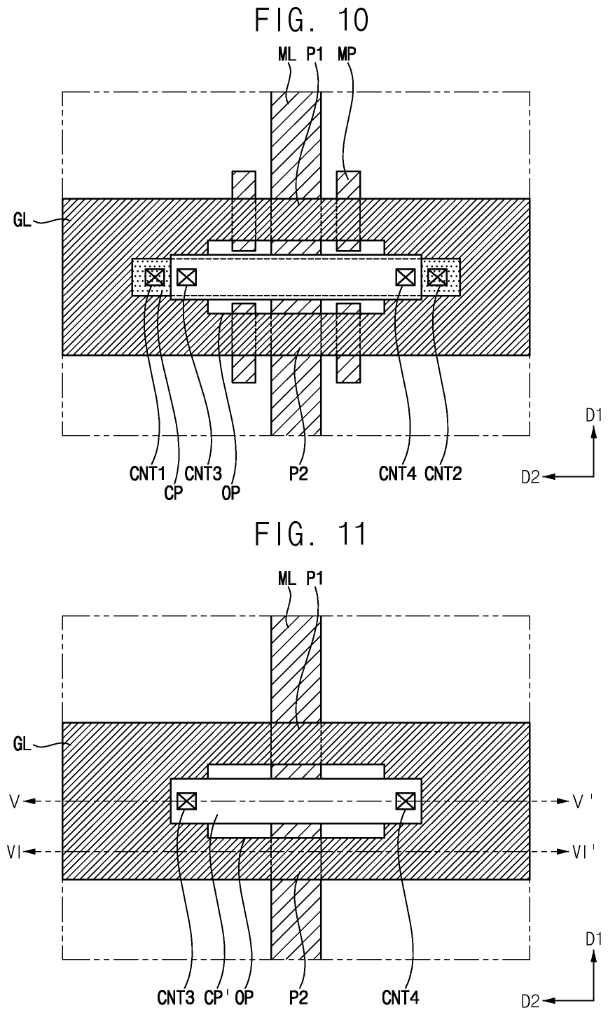

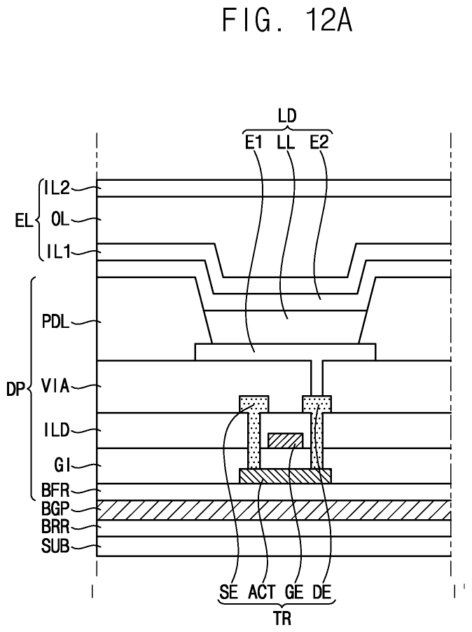

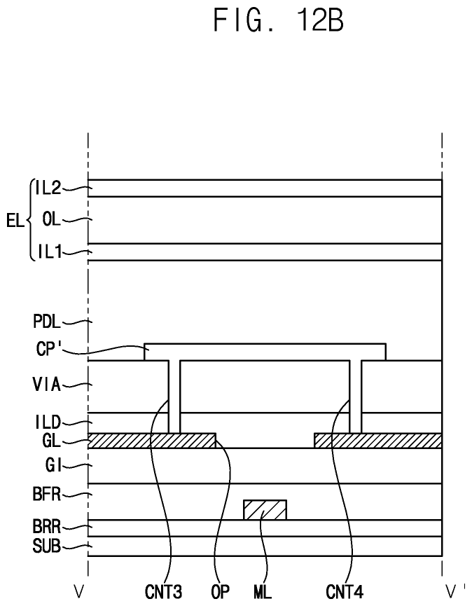

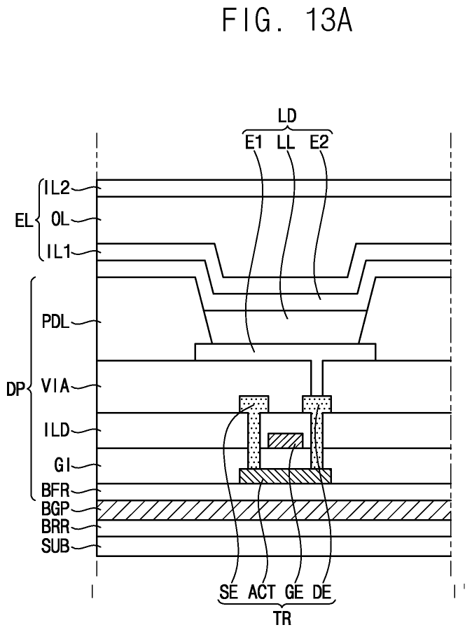

FIG. 11 is a plan view illustrating an embodiment of area A in FIG. 1. FIGS. 12A and 12B (together referred to as FIG. 12, hereinafter) are views illustrating a cross-sectional view taken along line I-I′ of FIG. 1 and a cross-sectional view taken along line V-V′ of FIG. 11, respectively. FIGS. 13A and 13B (together referred to as FIG. 13, hereinafter) are views illustrating a cross-sectional view taken along line I-I′ of FIG. 1 and a cross-sectional view taken along line VI-VI′ of FIG. 11, respectively. FIGS. 14A and 14B are views illustrating a cross-sectional view taken along line I-I′ of FIG. 1 and a cross-sectional view taken along line VI-VI′ of FIG. 11, respectively.

A display device 10 described with reference to FIGS. 11 to 14 may be similar to the display device 10 described with reference to FIG. 6 except for a conductive pattern CP′. Accordingly, among a description of the display device 10 described with reference to FIGS. 11 to 14, a description that overlaps with the display device 10 described with reference to FIG. 6 may be omitted.

Referring to FIGS. 11 and 13, a conductive pattern CP′ may be disposed on the same layer as the pixel electrode E1. That is, the conductive pattern CP′ may be disposed on the second insulation layer VIA.

The conductive pattern CP′ may be connected to the gate line GL through at least two contacts CNT3 and CNT4. Each of the contacts CNT3 and CNT4 may be a through hole penetrating the first insulation layer ILD and the second insulation layer VIA. For example, the conductive pattern CP′ may be connected to the gate line GL through two contacts CNT3 and CNT4. However, the present disclosure is not limited thereto.

The contacts CNT3 and CNT4 may be spaced apart from each other in the second direction D2. The opening OP may be positioned between the contacts CNT3 and CNT4 in the plan view. In addition, the metal line ML may also be positioned between the contacts CNT3 and CNT4 in the plan view. That is, the contacts CNT3 and CNT4 may be disposed adjacent to the front end GLa and the rear end GLb of the area of the gate line GL branching to have the plurality of paths, respectively.

The first portion P1 and the second portion P2 of the gate line GL may be spaced apart from the conductive pattern CP′ in the plan view.

In an embodiment, as the display device 10 further includes the conductive pattern CP′ connected to the gate line GL, on the gate line GL, the gate signal may be transmitted through the conductive pattern CP′ without interruption. Specifically, when a short circuit occurs in the display device 10 after the pixel electrode E1 and the conductive pattern CP′ are formed, both the first portion P1 and the second portion P2 of the gate line GL of the gate line GL may be cut to eliminate the short circuit. Even in this case, the cut gate line GL may transmit the gate signal through the conductive pattern CP′. Accordingly, the display device may be repaired even if both the first portion P1 and the second portion P2 of the gate line GL are cut due to an invisible defect in the repair process of the display device 10.

In an embodiment, for example, the display device 10 includes a display area DA, a metal line ML which is connected to the display area DA, transmits a first signal to the display area DA and extends in a first direction D1, a gate line GL which is connected to the display area DA, transmits a second signal to the display area DA and extends in a second direction D2 crossing the first direction D1, where the gate line GL crossing the metal line ML defines two overlapping portions of the gate line GL which are spaced apart from each other along the first direction D1 (e.g., the first portion P1 and the second portion P2) and define a gap of the gate line GL (e.g., the opening OP) therebetween, and a bridge pattern (e.g., the conductive pattern CP, the bridge pattern BP and/or the conductive pattern CP′) extending along the two overlapping portions of the gate line GL and crossing the metal line ML, the bridge pattern contacting the gate line GL at two contact locations along the gate line GL (e.g., at the two contacts CNT1 and CNT2 or the two contacts CNT3 and CNT4).

Referring to FIGS. 11, 12, and 14, at least one first hole H1 may be defined in the first insulation layer ILD, and at least one second hole H2 may be defined in the second insulation layer VIA. The first hole H1 and the second hole H2 may overlap each other, and the first hole H1 and the second hole H2 together, may form a hole portion HP. The hole portion HP exposes the gate line GL to outside an insulating layer, such as the first insulation layer ILD and the second insulation layer VIA taken together with each other.

For example, the display device 10 may form at least four hole portions HP. However, the present disclosure is not limited thereto.

Each of the four hole portions HP may overlap at least one of the first portion P1 and the second portion P2 in the plan view. The four hole portions HP may be spaced apart from the metal line ML in the plan view. The hole portions HP may be formed in an area to which a laser is irradiated in the repair process. That is, the hole portions HP correspond to a repair location or cutting location.

In an embodiment, as the hole portions HP are defined in the first insulation layer ILD and the second insulation layer VIA, a laser may easily cut the gate line GL through the hole portions HP since the gate line GL is exposed to outside the collective insulating layer. However, the present disclosure is not limited thereto, and in an embodiment, the hole portions HP may not be defined in the first insulation layer ILD and the second insulation layer VIA (see FIG. 13).

However, the present disclosure is not limited thereto, and the hole portions HP of FIG. 14 may be applied to the embodiments of FIGS. 2 to 12.

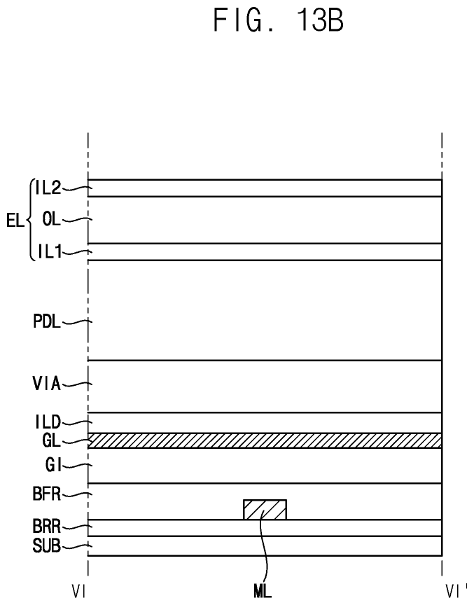

FIG. 15 is a plan view illustrating an embodiment of an area A in FIG. 1.

Among a description of the display device 10 described with reference to FIG. 15, a description that overlaps with the display device 10 described with reference to FIGS. 4 and 11 may be omitted.

Referring to FIG. 15, the display device 10 may further include at least one metal pattern MP. The metal pattern MP may be disposed on the same layer as the metal line ML. The metal pattern MP may overlap at least one of the first portion P1 and the second portion P2 in the plan view. The metal pattern MP may be spaced apart from the metal line ML.

For example, the display device 10 may include four metal patterns MP. The metal patterns MP may be disposed with the metal line ML interposed therebetween in the plan view.

In an embodiment, when the gate line GL is cut with a laser during the repair process of the display device 10, the laser is irradiated onto the metal patterns MP, corresponding to cutting positions, the substrate SUB included in the display device 10 may be prevented from being damaged.

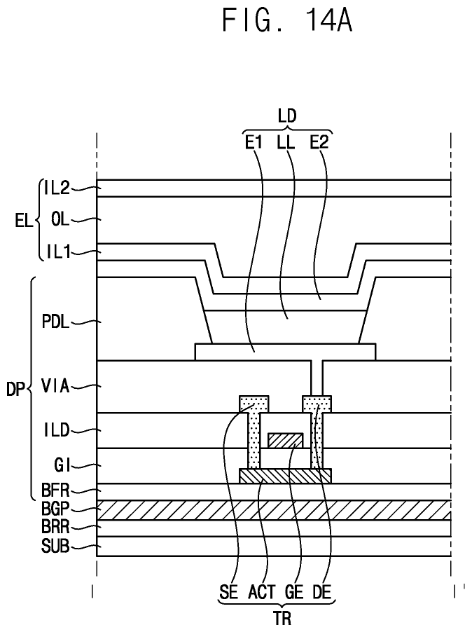

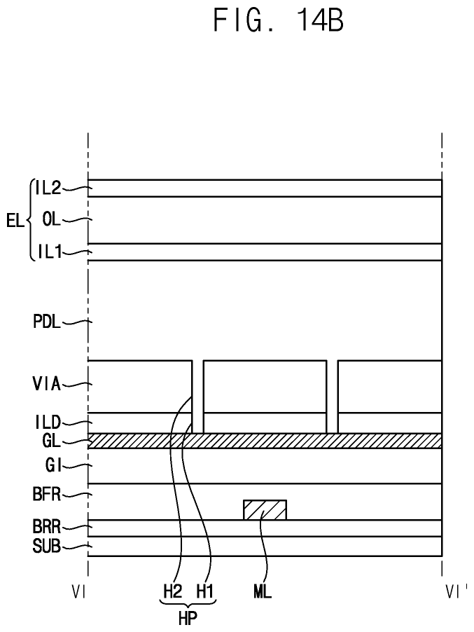

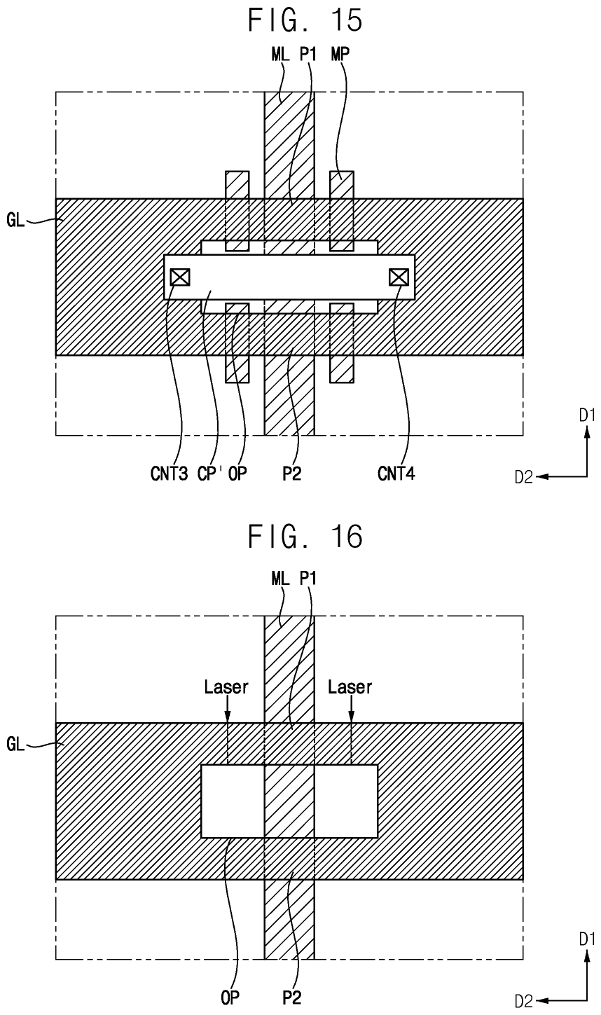

FIGS. 16 to 20 are views illustrating a repair method according to an embodiment of the present disclosure.

For example, the repair method illustrated in FIGS. 16 to 20 may be a method for repairing the display device 10 illustrated in FIGS. 1 to 3. Accordingly, overlapping descriptions may be omitted.

In a process of manufacturing a display device (e.g., the display device 10 of FIG. 1), if a short circuit occurs between the gate line GL and the metal line ML, the display device 10 may be cut using a cutting means as a cutting tool, such as a laser. A repair process may be performed by cutting both ends of the gate line GL. That is, the repair process including electrically disconnecting the gate line GL at more than one location.

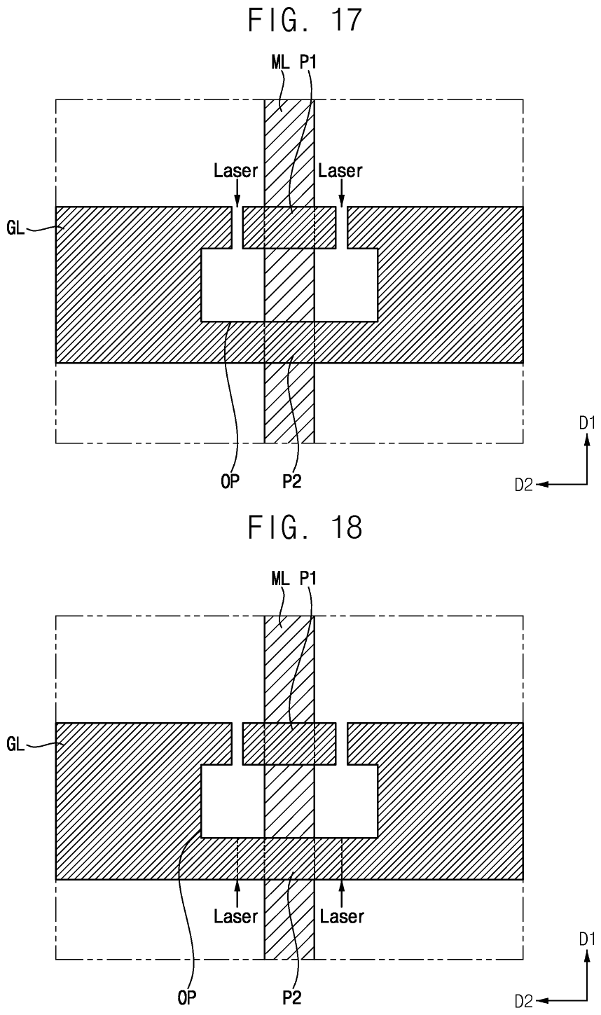

Referring to FIGS. 16 and 17, both ends of the short circuit area of the gate line GL may be cut using the cutting means such as a laser. For example, both of opposing ends of the first portion P1 of the gate line GL may be cut, such as at the locations indicated by ‘Laser’. A first hole or break may be formed in the gate line GL, at the first portion P1, along a line cut by a laser. The first hole may extend an entire width of the first portion P1 (e.g., along the first direction) and may extend an entire thickness (e.g., along the third direction, such as into the view of FIG. 16) The short circuit area of the gate line GL may be electrically separated from the metal line ML due to the hole.

Referring further to FIGS. 18 and 19, even after the both ends of the first portion P1 are cut, the short circuit may not be resolved. In this case, both of opposing ends of the second portion P2 of the gate line GL may be additionally cut. A second hole may be formed in the second portion P2 along a line cut by a laser. The short circuit area of the gate line GL may be electrically separated from the metal line ML due to the second hole.

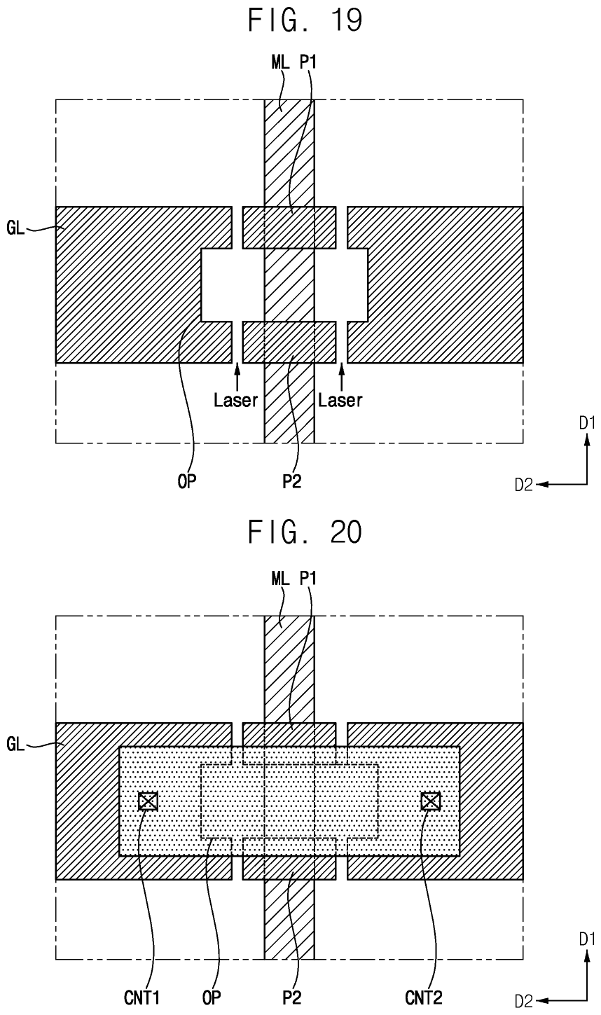

Referring further to FIG. 20, after the first portion P1 and the second portion P2 are cut, a conductive pattern CP may be formed (or provided) on the gate line GL. The conductive pattern CP may be connected to the gate line GL through two contacts CNT1 and CNT2.

In an embodiment, even when both the first portion P1 and the second portion P2 are cut, the gate line GL may provide an electrical path along the length thereof due to the conductive pattern CP bypassing the disconnected portions of the gate line GL. Accordingly, the gate signal may be transmitted through the gate line GL and the conductive pattern CP, while solving the short circuit of the display device 10.

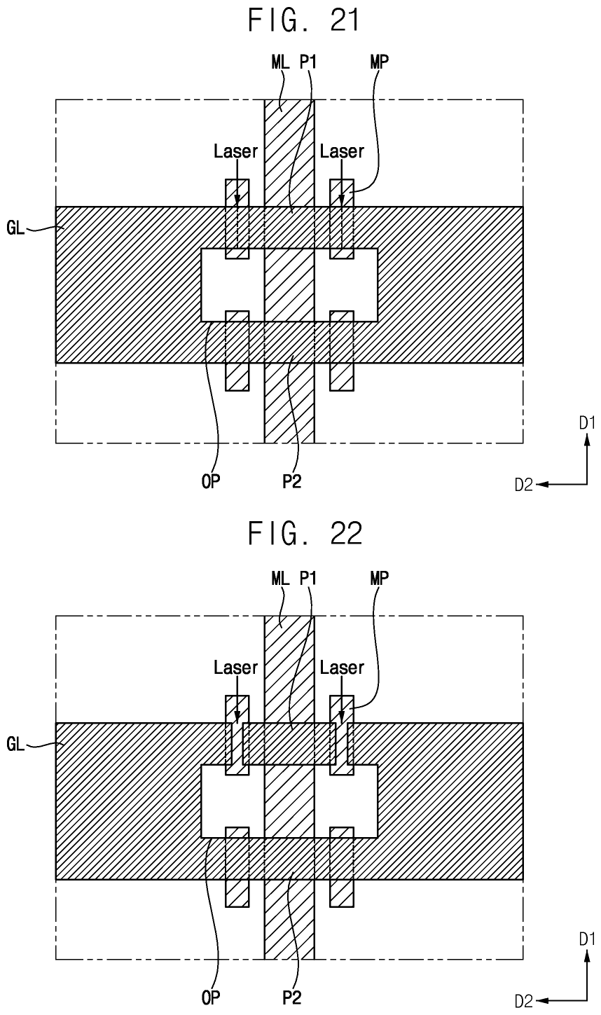

FIGS. 21 to 23 are views illustrating an embodiment of a repair process.

For example, a repair method illustrated in FIGS. 21 to 23 may be a method for repairing the display device 10 illustrated in FIGS. 4 and 5. Accordingly, overlapping descriptions may be omitted.

Referring to FIGS. 21 and 22, both of opposing ends of the short circuit area of the gate line GL may be cut using a cutting means such as a laser. For example, both ends of the first portion P1 of the gate line GL may be cut. A hole may be formed in the first portion P1 along a line cut by a laser. The short circuit area of the gate line GL may be electrically separated from the metal line ML due to the hole.

In an embodiment, the metal pattern MP may be disposed under the gate line GL, along a line cut by the laser of the gate line GL (e.g., a cutting line). For example, four metal patterns MP overlapping the first portion P1 and the second portion P2 may be disposed under the gate line GL, along a plurality of cutting lines, respectively.

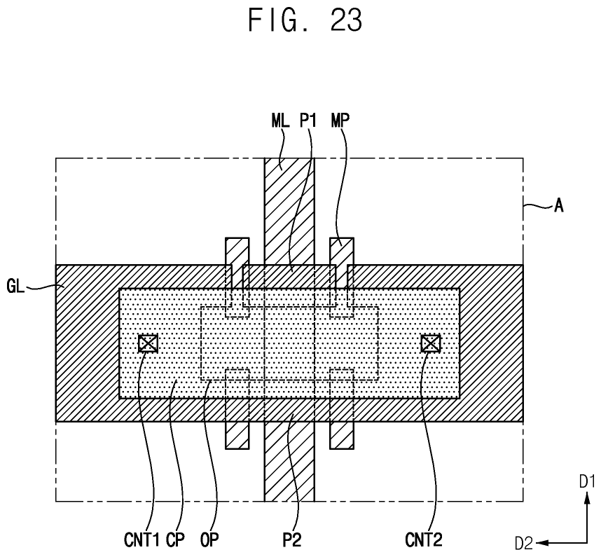

Referring further to FIG. 23, after the first portion P1 or the second portion P2 is cut, a conductive pattern CP may be formed on the gate line GL. The conductive pattern CP may be connected to the gate line GL through two contacts CNT1 and CNT2.

In an embodiment, when the gate line GL is cut with a laser along the cut line, as the laser is irradiated onto the metal patterns MP, a substrate (e.g. the substrate SUB of FIG. 3) included in the display device 10 may be prevented from being damaged due to the metal patterns MP being above the substrate SUB and below the gate line GL.

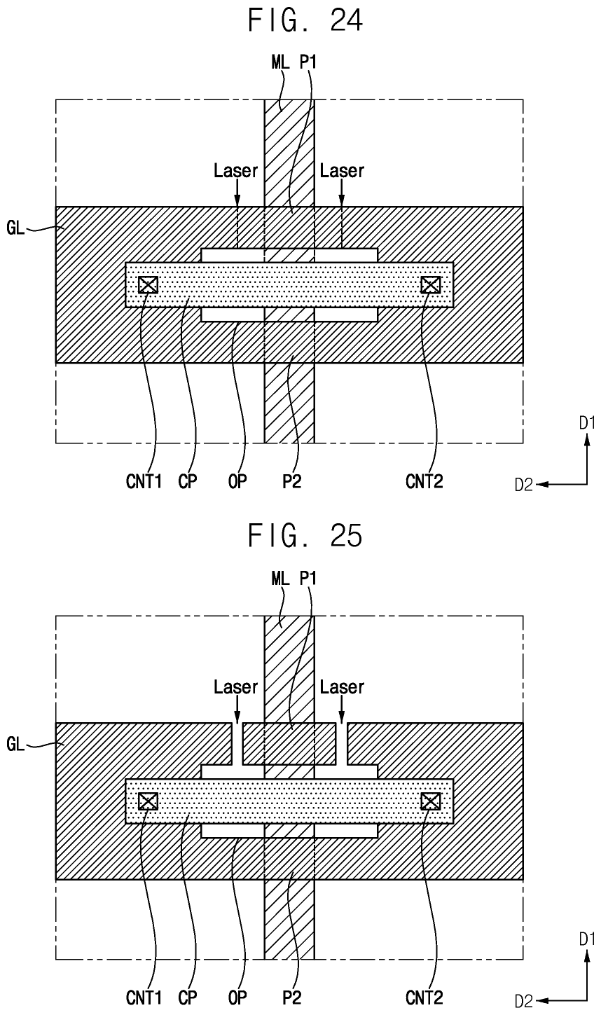

FIGS. 24 and 25 are views illustrating an embodiment of a repair process.

For example, a repair method illustrated in FIGS. 24 and 25 may be a method for repairing the display device 10 illustrated in FIG. 6. Accordingly, overlapping descriptions may be omitted.

Referring to FIGS. 24 and 25, the short circuit may occur after a conductive pattern CP, a source electrode (e.g., the source electrode SE of FIG. 3), and a drain electrode (e.g., the drain electrode DE of FIG. 3) are formed. formation. In this case, both of opposing ends of the short circuit area of the gate line GL may be cut using a cutting means such as a laser. For example, both ends of the first portion P1 of the gate line GL may be cut. A hole may be formed in the first portion P1 along a line cut by a laser. The short circuit area of the gate line GL may be electrically separated from the metal line ML due to the hole.

In an embodiment, since the first portion P1 and the second portion P2 of the gate line GL are spaced apart from the conductive pattern CP in the plan view, both ends of the first portion P1 or the second portion P2 are cut, the conductive pattern CP may not be damaged.

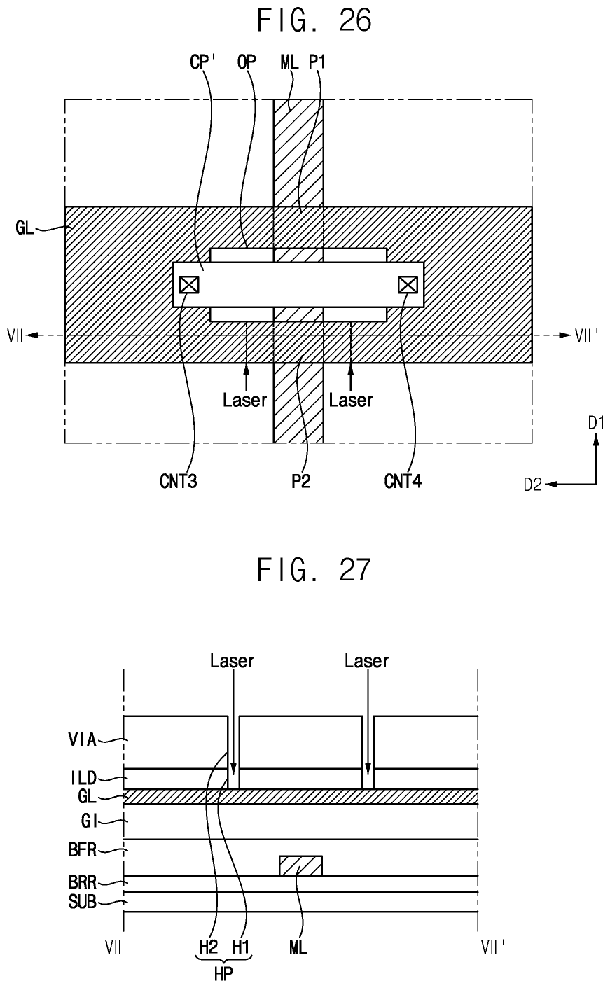

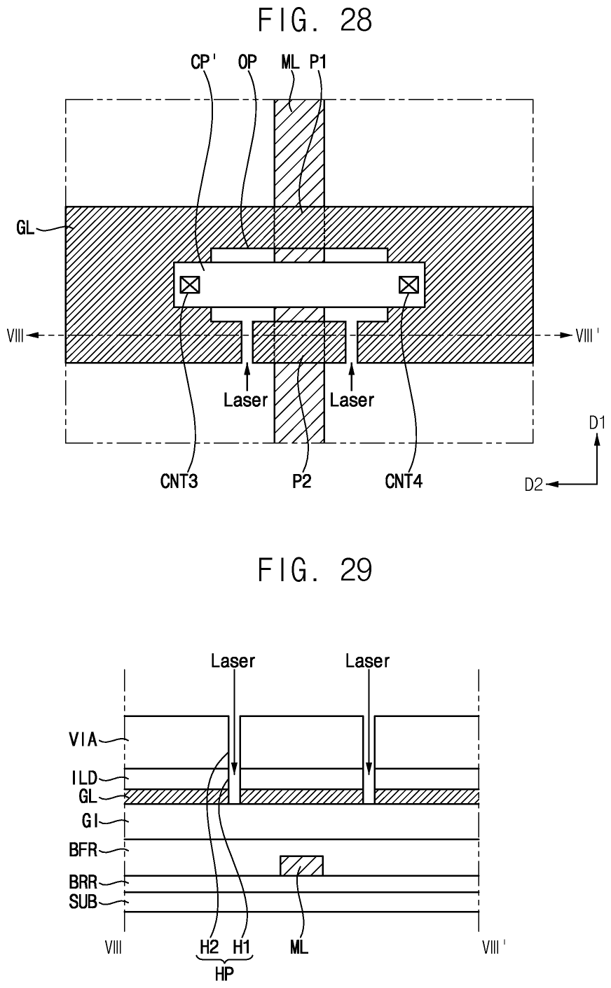

FIGS. 26 to 29 are views illustrating an embodiment of a repair process. FIG. 27 is a cross-sectional view taken along line VII-VII′ of FIG. 26. FIG. 29 is a cross-sectional view taken along line VIII-VIII′ of FIG. 28.

For example, a repair method illustrated in FIGS. 26 to 29 may be a method for repairing the display device 10 illustrated in FIGS. 11 to 14. Accordingly, overlapping descriptions may be omitted.

Referring to FIGS. 26 to 29, during a process of manufacturing the display device after the first insulation layer ILD, the second insulation layer VIA, the pixel electrode E1, and the conductive pattern CP′ are formed, a short circuit may occur. Similarly, both ends of the short circuit area of the gate line GL may be cut using a cutting means such as a laser. For example, both ends of the second portion P2 of the gate line GL may be cut. A hole may be formed in the second portion P2 along a line cut by a laser. The short circuit area of the gate line GL may be electrically separated from the metal line ML due to the hole.

In an embodiment, when the first insulation layer ILD is formed, at least one first hole H1 may be formed in the first insulation layer ILD. Also, when the second insulation layer VIA is formed, at least one second hole H2 overlapping the first hole H1 may be formed in the second insulation layer VIA. The first hole H1 and the second hole H2 overlapping each other may form a hole portion HP.

For example, four hole portions HP may be formed in the first insulation layer ILD and the second insulation layer VIA. Each of the four hole portions HP may be formed to overlap with at least one of the first portion P1 and the second portion P2 in the plan view. The hole portions HP may be formed in an area to which a laser is irradiated. That is, the hole portions HP may be formed to overlap the line cut by the laser.

In an embodiment, as the hole portions HP are formed in the first insulation layer ILD and the second insulation layer VIA, a laser may be easily irradiated to the gate line GL through the hole portions HP. Accordingly, the gate line GL may be easily cut.

The display devices according to embodiments may be applied to a display device included in a computer, a notebook, a mobile phone, a smartphone, a smart pad, a PMP, a PDA, an MP3 player, or the like.

Although the display devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a display area;
a metal line which is connected to the display area, transmits a first signal to the display area and extends along a first direction;
a gate line which is connected to the display area, transmits a second signal to the display area and extends along a second direction crossing the first direction;
the gate line crossing the metal line and defining an opening of the gate line which overlaps the metal line; and
a first bridge pattern extending across the opening in the gate line and crossing the metal line, the first bridge pattern contacting the gate line at two contact locations along the gate line.

2. The display device of claim 1, wherein
the two contact locations are spaced apart from each other along the second direction, and
the opening is defined between the two contact locations, along the second direction.

3. The display device of claim 1, wherein
the gate line includes a first portion and a second portion spaced apart from each other, and
each of the first portion and the second portion overlaps the metal line.

4. The display device of claim 3, wherein
the first portion of the gate line and the second portion of the gate line are spaced apart from each other along the first direction, and
the opening is positioned between the first portion and the second portion, along the first direction.

5. The display device of claim 4, wherein the first portion and the second portion of the gate line are spaced apart from the first bridge pattern, along the first direction.

6. The display device of claim 3, further comprising:
a buffer layer on the metal line;
an active pattern of a transistor, on the buffer layer;
a gate electrode of the transistor, on the active pattern and overlapping the active pattern;
a first insulation layer on the gate electrode;
a source electrode and a drain electrode of the transistor which are on the first insulation layer and connected to the active pattern;
a second insulation layer on the source electrode and the drain electrode; and
a pixel electrode of a light-emitting element, on the second insulation layer and connected to the transistor.

7. The display device of claim 6, wherein the gate line is in a same layer as the gate electrode.

8. The display device of claim 6, wherein the first bridge pattern is in a same layer as the source electrode and the drain electrode.

9. The display device of claim 8, further comprising:
a second bridge pattern in a same layer as the pixel electrode.

10. The display device of claim 9, wherein the second bridge pattern is in a different layer from the first bridge pattern, and connected to the first bridge pattern.

11. The display device of claim 9, wherein the second bridge pattern is spaced apart from the first portion and the second portion of the gate line, along the first direction.

12. The display device of claim 9, wherein
a first hole is defined in the first insulation layer,
a second hole overlapping the first hole, is defined in the second insulation layer, and
the first hole and the second hole together form a hole portion which exposes the gate line to outside both the first insulation layer and the second insulation layer.

13. The display device of claim 12, wherein the hole portion overlaps the gate line at the first portion or the second portion, and is spaced apart from the metal line.

14. The display device of claim 6, wherein the first bridge pattern is in a same layer as the pixel electrode.

15. The display device of claim 3, further comprising:
a metal pattern in a same layer as the metal line, the metal pattern overlapping the gate line at the first portion or the second portion and spaced apart from the metal line.

16. The display device of claim 1, wherein
the metal line transmits a data signal to the display area, and
the gate line transmits a gate signal to the display area.

17. A display device comprising:
a display area;
a metal line which is connected to the display area, transmits a first signal to the display area and extends along a first direction;
a gate line which is connected to the display area, transmits a second signal to the display area and extends along a second direction crossing the first direction;
the gate line crossing the metal line to define two overlapping portions of the gate line which are spaced apart from each other along the first direction and define a gap of the gate line therebetween; and
a bridge pattern extending along the two overlapping portions of the gate line and crossing the metal line, the bridge pattern contacting the gate line at two contact locations along the gate line.

18. The display device of claim 17, wherein the two overlapping portions of the gate line meet each other at a front end of the gap and at a rear end of the gap which is opposite to the front end along the second direction.

19. The display device of claim 18, wherein the two contact locations are respectively further from the gap than the front end and the rear end.

20. The display device of claim 17, wherein the two overlapping portions of the gate line are spaced apart from the bridge pattern, along the first direction.
